(19) United States
(12) Patent Application Publication
(10) Pub. No.: US 2025/0255117 A1
(43) Pub. Date: Aug. 7, 2025

(54) LIGHT-EMITTING DEVICE, DISPLAY APPARATUS INCLUDING THE SAME, ELECTRONIC DEVICE, AND METHOD FOR MANUFACTURING LIGHT-EMITTING DEVICE

(71) Applicant: CANON KABUSHIKI KAISHA, Tokyo (JP)

(72) Inventors: HIROMASA TSUBOI, Tokyo (JP); MASATO YAJIMA, Tokyo (JP)

(21) Appl. No.: 19/039,233

(22) Filed: Jan. 28, 2025

(30) Foreign Application Priority Data
Feb. 2, 2024 (JP) 2024-014805

(51) Int. Cl. H10K 59/123; H10D 30/60; H10D 30/67; H10K 59/12; H10K 59/131

(52) U.S. Cl. CPC H10K 59/123; H10D 30/601; H10D 30/6715; H10K 59/1201; H10K 59/131

(57) ABSTRACT

The present disclosure provides, as a display apparatus in which a leakage current in a light-emitting element is reduced, a light-emitting device, a first transistor and a second transistor, an insulating layer and a third transistor, wherein a source of the first transistor is connected to a gate electrode of the second transistor, wherein a drain of the second transistor is connected to the light-emitting element, wherein the light-emitting device includes a silicide layer in at least any one of a source, a drain, or a gate electrode of the third transistor, and wherein the light-emitting device includes a region where a silicide layer is not provided between at least any one of the source, a drain, or a gate electrode of the first transistor or a source, the drain, or the gate electrode of the second transistor and the insulating layer.

### BACKGROUND OF THE INVENTION

### Field of the Invention

The present disclosure relates to a light-emitting device, and for example, relates to a light-emitting device including a light-emitting element, a display apparatus including the same, an electronic device, and a method for manufacturing a light-emitting device.

### Description of Related References

In recent years, a display apparatus including in an array a light-emitting element that emits light at a luminance according to a current flowing through an element is known. An organic electroluminescent (EL) element is used as the light-emitting element. The display apparatus greatly expands its purposes and requires a high definition and a high function according to the purpose.

Japanese Patent Application Laid-Open No. 2020-71323 discusses a display apparatus including a semiconductor compound layer (a silicide layer) of a high-melting-point metal in the source and the drain of a driving transistor in a driving circuit of an organic light-emitting element.

In the source and the drain of the transistor discussed in Japanese Patent Application Laid-Open No. 2020-71323, the silicide layer is disposed. The silicide layer can reduce the resistance of the transistor. The provision of the silicide layer, however, can also decrease the characteristics of the light-emitting element.

### SUMMARY OF THE INVENTION

The present disclosure is directed to providing a light-emitting device in which a decrease in the characteristics of the light-emitting device due to the provision of a silicide layer is reduced.

The present disclosure provides a light-emitting device comprising: a light-emitting element, a first transistor and a second transistor provided on a first surface of a silicon substrate, an insulating layer disposed between the light-emitting element and the first surface, and a third transistor provided in a peripheral circuit configured to supply an image signal to the first transistor, wherein either of a source or a drain of the first transistor is connected to a gate electrode of the second transistor, wherein either of a source or a drain of the second transistor is connected to the light-emitting element, wherein the light-emitting device includes a silicide layer in at least any one of a source, a drain, or a gate electrode of the third transistor, and the silicide layer is in contact with the insulating layer, and wherein the light-emitting device includes a region where a silicide layer is not provided between at least any one of the source, the drain, or a gate electrode of the first transistor or the source, the drain, or the gate electrode of the second transistor and the insulating layer.

Further features of the present disclosure will become apparent from the following description of exemplary embodiments with reference to the attached drawings.

### BRIEF DESCRIPTION OF THE DRAWINGS

FIG. 1 is a schematic diagram illustrating an example of a light-emitting device according to a first exemplary embodiment.

FIG. 2 is a circuit diagram illustrating an example of a pixel circuit of the light-emitting device according to the first exemplary embodiment.

FIG. 3A is a plan view illustrating an example of the circuit of the light-emitting device according to the first exemplary embodiment. FIG. 3B is a plan view illustrating an example of a peripheral circuit transistor of the light-emitting device according to the first exemplary embodiment.

FIG. 4A is a cross-sectional view illustrating an example of the light-emitting device according to the first exemplary embodiment. FIG. 4B is a cross-sectional view illustrating an example of the peripheral circuit transistor of the light-emitting device according to the first exemplary embodiment.

FIG. 5A is a cross-sectional view illustrating an example of a light-emitting device according to a second exemplary embodiment. FIG. 5B is a cross-sectional view illustrating a variation of the light-emitting device according to the second exemplary embodiment.

FIGS. 6A to 6D are schematic diagrams illustrating an example of a manufacturing process for a light-emitting device according to an exemplary embodiment of the present disclosure.

FIG. 7A is a cross-sectional view illustrating an example of a light-emitting device according to a third exemplary embodiment. FIG. 7B is a cross-sectional view illustrating an example of a light-emitting device according to a fourth exemplary embodiment.

FIG. 8A is a cross-sectional view illustrating an example of a light-emitting device according to a fifth exemplary embodiment. FIG. 8B is a cross-sectional view illustrating an example of the light-emitting device according to the fifth exemplary embodiment.

FIG. 9 is a schematic diagram illustrating a light-emitting device according to a sixth exemplary embodiment.

FIG. 10 is a circuit diagram illustrating an example of a pixel circuit according to the sixth exemplary embodiment.

FIG. 11 is a plan view illustrating an example of the pixel circuit according to the sixth exemplary embodiment.

FIG. 12 is a cross-sectional view illustrating an example of the light-emitting device according to the sixth exemplary embodiment.

FIG. 13 is a schematic diagram illustrating an example of a light-emitting device according to a seventh exemplary embodiment.

FIG. 14 is a circuit diagram illustrating an example of a pixel circuit of the light-emitting device according to the seventh exemplary embodiment.

FIG. 15 is a plan view illustrating an example of the pixel circuit according to the seventh exemplary embodiment.

FIG. 16 is a cross-sectional view illustrating an example of the light-emitting device according to the seventh exemplary embodiment.

FIG. 17 is an example of an inverter circuit in a vertical scanning circuit according to an eighth exemplary embodiment.

FIG. 18 is a plan view illustrating an example of the circuit according to the eighth exemplary embodiment.

FIG. 19 is a cross-sectional view illustrating an example of a light-emitting device according to the eighth exemplary embodiment.

FIG. 20 is a schematic diagram illustrating an example of a display apparatus according to an exemplary embodiment of the present disclosure.

FIG. 21A is a schematic diagram illustrating an example of an imaging apparatus according to an exemplary embodiment of the present disclosure. FIG. 21B is a schematic diagram illustrating an example of an electronic device according to an exemplary embodiment of the present disclosure.

FIGS. 22A and 22B are schematic diagrams illustrating examples of a display apparatus according to an exemplary embodiment of the present disclosure.

FIGS. 23A and 23B are schematic diagrams illustrating examples of a wearable device according to an exemplary embodiment of the present disclosure.

### DETAILED DESCRIPTION

A light-emitting device according to an exemplary embodiment of the present disclosure includes a light-emitting element, a first transistor and a second transistor provided on a first surface of a silicon substrate, an insulating layer disposed between the light-emitting element and the first surface; and a third transistor provided in a peripheral circuit configured to supply an image signal to the first transistor, wherein either of a source and a drain of the first transistor is connected to a gate electrode of the second transistor, wherein either of a source and a drain of the second transistor is connected to the light-emitting element, wherein the light-emitting device includes a silicide layer in at least any one of a source, a drain, or a gate electrode of the third transistor, and the silicide layer is in contact with the insulating layer, and wherein the light-emitting device includes a region where a silicide layer is not provided between at least any one of the source, the drain, or a gate electrode of the first transistor or the source, the drain, or the gate electrode of the second transistor and the insulating layer. That is to say, the region where the silicide layer is not provided may be only the source, only the drain, or only the gate electrode of the first transistor. The region where the silicide layer is not provided may be combination thereof. The region where the silicide layer is not provided may be all of the source, the drain, and a gate electrode of the first transistor. In other words, the light-emitting device includes a region where a silicide layer is not provided between at least one selected from the group consisting of the source, the drain, and a gate electrode of the first transistor or the group consisting of the source, the drain, and the gate electrode of the second transistor and the insulating layer.

The light-emitting device includes a region where a silicide layer is not provided between at least any one of the source, the drain, or the gate electrode of the first or second transistor and the insulating layer, whereby it is possible to reduce a leakage current in this region.

A light-emitting device according to another exemplary embodiment of the present disclosure includes a light-emitting element, a first transistor and a second transistor provided on a first surface of a silicon substrate, and a third transistor provided in a peripheral circuit configured to supply an image signal to the first transistor, wherein either of a source and a drain of the first transistor is connected to a gate electrode of the second transistor, wherein either of a source and a drain of the second transistor is connected to the light-emitting element, wherein the light-emitting device includes a salicide structure in at least any one of a source, a drain, or a gate electrode of the third transistor, and wherein the light-emitting device does not include a salicide structure in at least any one of the source, the drain, or a gate electrode of the first transistor or the source, the drain, or the gate electrode of the second transistor.

The light-emitting device does not include a salicide structure in at least any one of the source, the drain, or the gate electrode of the first or second transistor, whereby it is possible to reduce a leakage current in this region.

Exemplary embodiments will be described in detail below with reference to the attached drawings. The following exemplary embodiments do not limit the disclosure according to the appended claims. Although a plurality of features is described in the exemplary embodiments, not all the plurality of features is essential for the disclosure, and the plurality of features may be optionally combined together. Further, in the attached drawings, the same or similar components are designated by the same reference numbers, and are not redundantly described.

In the following exemplary embodiments, there is described a driving transistor that is connected to the anode of an organic light-emitting element, and all transistors are P-type transistors. A light-emitting device according to the present disclosure, however, is not limited to this. All polarities and conductivity types may be opposite. Each transistor may be either a P-type transistor or an N-type transistor. To change the transistor, a potential to be supplied and connections may be appropriately changed according to the conductivity type and the polarity of the transistor.

In the following exemplary embodiments, a peripheral circuit may be provided on the same silicon substrate as a pixel transistor, or may be provided on a second silicon substrate different from a first silicon substrate on which a pixel transistor is provided.

In the specification, a light-emitting element may be an organic light-emitting element in which a light-emitting portion is a light-emitting layer having an organic compound, or may be an inorganic light-emitting element in which a light-emitting portion is composed of an inorganic compound.

The organic light-emitting element includes an organic layer including a light-emitting layer between the electrodes, namely the anode and the cathode, of the organic light-emitting element. The organic layer may appropriately include one or more of a hole injection layer, a hole transport layer, an electron injection layer, and an electron transport layer in addition to the light-emitting layer. A display apparatus including the organic light-emitting element is an example of the light-emitting device and is also referred to as an “organic light-emitting device”.

In the following exemplary embodiments, an example is described where the organic light-emitting element is used.

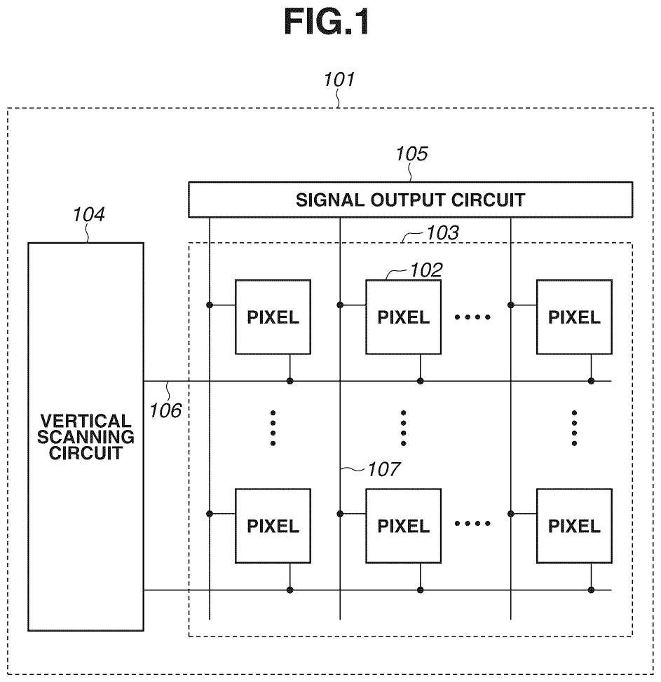

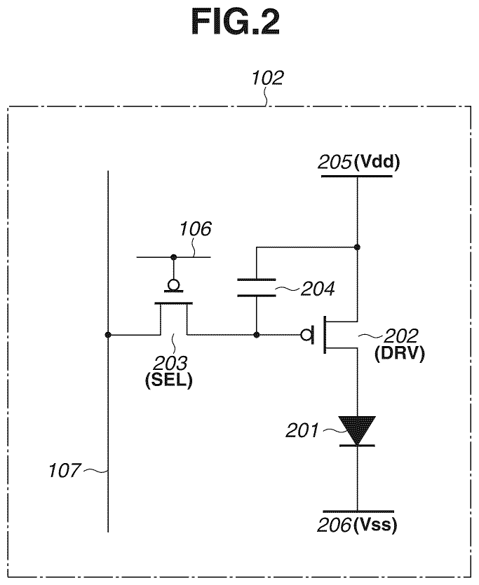

FIG. 1 is a schematic diagram of an example of a light-emitting device according to a first exemplary embodiment. A light-emitting device 101 includes a pixel array unit 103 and a peripheral circuit unit placed on the periphery of the pixel array unit 103. The pixel array unit 103 includes a plurality of pixels 102 two-dimensionally arranged in a matrix. Each pixel 102 includes an organic light-emitting element 201 (illustrated in FIG. 2).

The light-emitting device 101 includes the peripheral circuit unit that drives each pixel 102. For example, the peripheral circuit unit includes a vertical scanning circuit 104 and a signal output circuit 105. In the pixel array unit 103, a first scanning line 106 is disposed with respect to each pixel row along the row direction. A signal line 107 is disposed with respect to each pixel column along the column direction.

The first scanning line 106 is connected to the output end of a corresponding row of the vertical scanning circuit 104. The signal line 107 is connected to the output end of a corresponding column of the signal output circuit 105. The vertical scanning circuit 104 supplies a writing control signal for controlling the timing when a video signal is written to each pixel 102 of the pixel array unit 103 to the first scanning line 106. The signal output circuit 105 outputs a luminance signal having a voltage according to luminance information.

FIG. 2 is a circuit diagram illustrating an example of a pixel circuit included in the light-emitting device 101 in FIG. 1. A pixel 102 includes a light-emitting element 201, a driving transistor 202 (DRV), a writing transistor 203 (SEL), and a first capacitor element 204. One of the source and the drain of the driving transistor 202 is connected to a first electrode of the light-emitting element 201, and the other of the source and the drain of the driving transistor 202 is connected to a first power supply terminal 205 (hereinafter, “Vdd”). A second electrode of the light-emitting element 201 is connected to a second power supply terminal 206 (hereinafter, “Vss”).

One of the source and the drain of the writing transistor 203 is connected to the gate electrode of the driving transistor 202, and the other of the source and the drain of the writing transistor 203 is connected to the signal line 107. The gate electrode of the writing transistor 203 is connected to the first scanning line 106.

The first capacitor element 204 is connected between the gate and one of the source and the drain (the source in this case) of the driving transistor 202 and holds a luminance signal of the pixel 102 in the pixel 102. The first capacitor element 204 may be any of a parasitic capacitor, a gate-channel capacitor of a metal-oxide-semiconductor (MOS), a metal-insulator-metal (MIM) structure, and a metal-oxide-metal (MOM) structure.

In the present exemplary embodiment, the drain of the driving transistor 202 is connected to the anode of the light-emitting element 201, and the source of the driving transistor 202 is connected to the first power supply terminal 205 (Vdd).

The first capacitor element 204 is connected between the gate electrode of the driving transistor 202 and the source of the driving transistor 202 and holds a luminance signal of the pixel 102 in the pixel 102. The first capacitor element 204 according to the present exemplary embodiment is composed of a MIM structure.

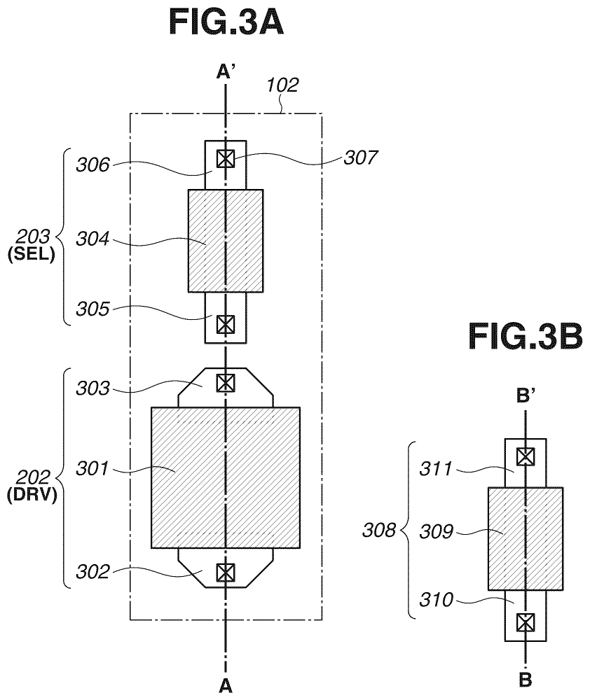

FIG. 3A is a plan view of an example of the circuit illustrated in FIG. 2. The driving transistor 202 includes a gate electrode 301, a source 302, and a drain 303.

The writing transistor 203 includes a gate electrode 304, a source 305, and a drain 306. Contact wires 307 are connected to wires in other layers.

FIG. 3B is a plan view of an example of a peripheral circuit transistor. A peripheral circuit transistor 308 includes a gate electrode 309, a source 310, and a drain 311. The peripheral circuit supplies an image signal to the writing transistor 203. The image signal is a signal for controlling the timing when the writing transistor 203 is turned on or a signal indicating a luminance signal.

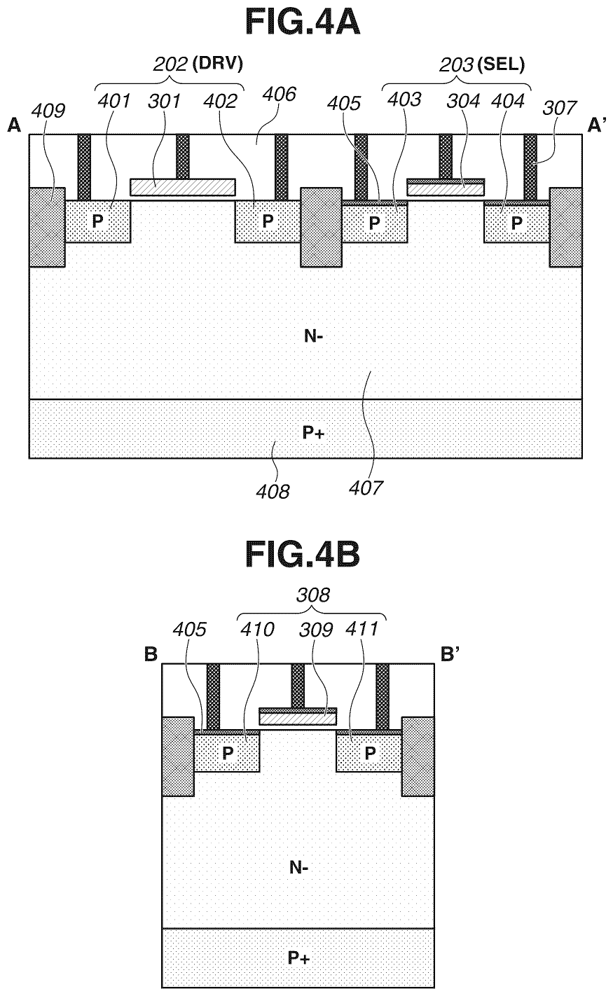

FIG. 4A is a cross-sectional view along A-A′ in the plan view illustrated in FIG. 3A. All transistors according to the present exemplary embodiment are provided on an N-type well layer 407 provided on a first surface of a P-type silicon substrate 408. Specifically, the driving transistor 202 and the writing transistor 203 are provided, and these transistors are separated by an insulator separation portion 409. The source 302 and the drain 303 of the driving transistor 202 are formed by P-type diffusion layers 401 and 402, respectively, and the source 305 and the drain 306 of the writing transistor 203 are formed by P-type diffusion layers 403 and 404, respectively. The insulator separation portion 409 may be any of shallow trench isolation (STI) separation, Local Oxidation of Silicon (LOCOS) separation, and N-type diffusion layer separation.

A silicide layer 405 can reduce the contact resistance between the source or the drain of a transistor and a contact wire 307. The silicide layer 405 may be a silicide layer formed using a salicide (self-aligned silicide) process.

The salicide process is performed, for example, by the steps of (a) forming a film of a metal element on a semiconductor layer, (b) silicidating the metal element, and (c) removing the metal element. First, a film having the metal element is formed on the surface of a semiconductor layer using a physical vapor deposition (PVD) method. Next, if the semiconductor layer is heated, the metal element on the semiconductor layer reacts, thereby forming a silicide. A region other than the semiconductor layer, such as a metal layer provided on an insulating layer such as a silicon oxide layer, is not silicidated and remains the metal layer.

Next, the metal layer provided on the insulating layer is selectively removed by a chemical solution process. By this step, if the insulating layer is not provided in the gate, the source, and the drain of a transistor, the silicide remains on the gate, the source, and the drain of the transistor. As described above, since a silicide is formed in a self-aligned manner, the above process is termed a “salicide process”.

If a semiconductor region to be a source or drain region and a metal such as a contact electrode are heated in the state where the semiconductor region and the metal are in contact with each other, there is a case where the contact portion between the semiconductor region and the metal is silicidated. In this case, a silicide is formed on the source or drain region.

Also in this case, however, the silicide is not provided in at least a part of a region where the source or drain region and the insulating layer are in contact with each other. In the specification of the present application, a silicide formed during the process of forming such a contact electrode is not included in a salicide structure or a silicide layer.

Examples of the metal element constituting the silicide layer include at least one selected from the group including titanium, nickel, cobalt, tungsten, molybdenum, tantalum, chromium, palladium, and platinum or an alloy having the at least one as a main component. As an example, a silicide layer provided in a source or drain region 211 of a transistor in a second semiconductor layer 200 is a cobalt silicide, and the metal element constituting the silicide layer is cobalt.

An insulating layer 406 is an insulating layer provided between the light-emitting element 201 and the first surface of the silicon substrate 408. The insulating layer 406 is also referred to as an “interlayer insulating layer” and forms a part of a wiring layer of the light-emitting device 101. As illustrated in FIG. 4A, the insulating layer 406 is an interlayer insulating layer closest to the silicon substrate 408. The contact electrodes 307 are in contact with the source 302, the drain 303, and the gate electrode 301 of the driving transistor 202 and the source 305, the drain 306, and the gate electrode 304 of the writing transistor 203 through openings provided in the insulating layer 406.

In the source 305, the drain 306, and the gate electrode 304 of the writing transistor 203, the silicide layer 405 is provided. On the other hand, in the source 302, the drain 303, and the gate electrode 301 of the driving transistor 202, the silicide layer 405 is not provided. Since the silicide layer 405 is provided in the writing transistor 203, the resistance between the writing transistor 203 and the contact electrodes 307 can be lowered. If only the lowering of resistance is taken into account, it is possible that the silicide layer 405 is also provided in the driving transistor 202. However, there is a possibility that a metal atom constituting the silicide layer 405 is diffused into a depletion layer of a transistor due to heat applied during the manufacturing process. This can generate dark electrons. This can result in a generation source of a leakage current flowing between the source 302 and the drain 303 of the driving transistor 202. If a leakage current is generated, the amount of current flowing through the light-emitting element 201 changes. Thus, variation in the luminance of the light-emitting element can occur. Accordingly, in the present exemplary embodiment, the silicide layer 405 is not provided in the driving transistor 202, whereby it is possible to reduce the generation of a leakage current and display high-quality black.

FIG. 4B is a cross-sectional view along B-B′ in the plan view illustrated in FIG. 3B. As illustrated in FIG. 4B, the source 310 and the drain 311 of the peripheral circuit transistor 308 are formed by P-type diffusion layers 410 and 411, respectively. In at least one of the source 310, the drain 311, and the gate electrode 309 of the peripheral circuit transistor 308, the silicide layer 405 is provided. The performance of the peripheral circuit transistor 308 according to the present exemplary embodiment is increased by lowering the resistance of the transistor 308, instead of reducing a leakage current.

That is, the light-emitting device according to the present exemplary embodiment has a configuration in which the light-emitting device includes a region where the silicide layer 405 is not provided between the source 302, the drain 303, and the gate electrode 301 of the driving transistor 202 and the insulating layer 406.

According to the configuration of the present exemplary embodiment, the silicide layer 405 is not disposed in the source 302 and the drain 303 of the driving transistor 202, whereby it is possible to reduce the diffusion of a metal atom in the silicide layer 405 into a depletion layer near the source 302 and the drain 303 of the driving transistor 202. This can reduce a leakage current flowing from the driving transistor 202 into the light-emitting element 201. Thus, it is possible to display high-quality black.

Although in the present exemplary embodiment, an example has been illustrated where the silicide layer 405 is not disposed in any of the source 302, the drain 303, and the gate electrode 301 of the driving transistor 202, it is possible to obtain the effect of reducing a leakage current compared to a conventional configuration also with a configuration in which the light-emitting device does not include the silicide layer 405 in at least parts of the source 302, the drain 303, and the gate electrode 301 of the driving transistor 202, and includes the silicide layer 405 in any of the regions of the source 302, the drain 303, and the gate electrode 301 of the driving transistor 202. That is, the effect is obtained by the light-emitting device including a region where the light-emitting device does not include the silicide layer 405 in a part of the source 302, a part of the drain 303, or a part of the gate electrode 301 of the driving transistor 202, and is not limited to the description of the present exemplary embodiment.

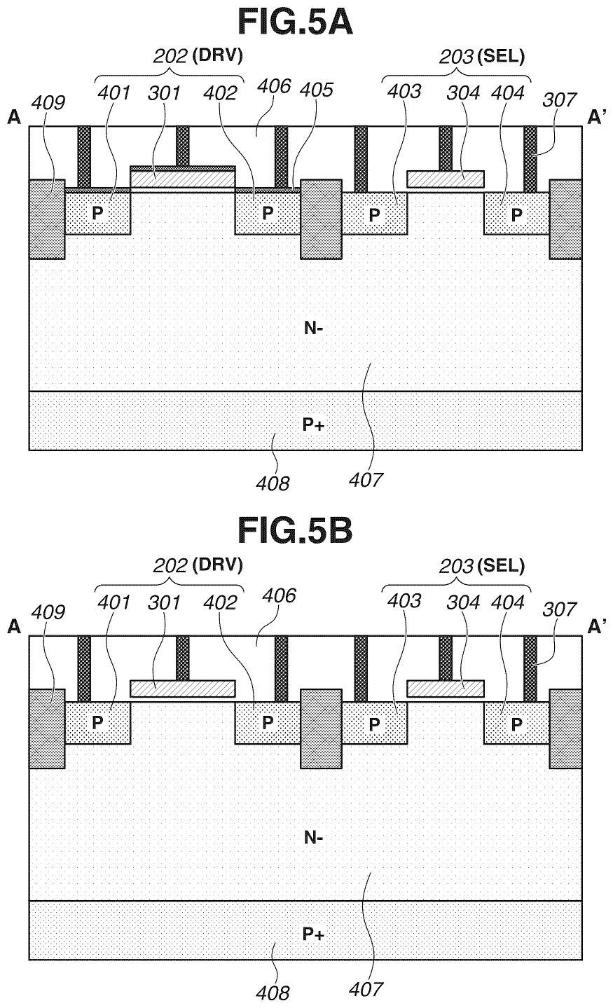

FIG. 5A is a cross-sectional view of a light-emitting device according to a second exemplary embodiment. The present exemplary embodiment is different from the first exemplary embodiment in that the silicide layer 405 is provided between the source 302, the drain 303, and the gate electrode 301 of the driving transistor 202 and the insulating layer 406. The present exemplary embodiment is also different from the first exemplary embodiment in that the silicide layer 405 is not provided between the source 305, the drain 306, and the gate electrode 304 of the writing transistor 203 and the insulating layer 406. In the first exemplary embodiment, a description has been given of the configuration of a pixel circuit for reducing the generation of a leakage current in the driving transistor 202. In contrast, in the present exemplary embodiment, a description is given of the configuration of a pixel circuit for reducing a leakage current in the writing transistor 203.

In FIG. 5A, the silicide layer 405 is provided in the source 302, the drain 303, and the gate electrode 301 of the driving transistor 202, and the silicide layer 405 and the insulating layer 406 are in contact with each other. On the other hand, the silicide layer 405 is not provided between the source 305, the drain 306, and the gate electrode 304 of the writing transistor 203 and the insulating layer 406, and the source 305, the drain 306, and the gate electrode 304 of the writing transistor 203 and the insulating layer 406 are in contact with each other. The peripheral circuit transistor 308 is similar to that illustrated in FIG. 4B.

That is, the light-emitting device according to the present exemplary embodiment has a configuration in which the light-emitting device includes a region where the silicide layer 405 is not provided between the source 305, the drain 306, and the gate electrode 304 of the writing transistor 203 and the insulating layer 406.

With the above configuration, the resistance between the driving transistor 202 and the contact electrodes 307 is reduced. On the other hand, the writing transistor 203 has a configuration in which the writing transistor 203 does not include the silicide layer 405, and a leakage current between the source 305 and the drain 306 of the writing transistor 203 is reduced.

The source 305 or the drain 306 of the writing transistor 203 is connected to one of the electrodes of the first capacitor element 204. In a case where a leakage current in the writing transistor 203 is reduced, it is possible to reduce charges flowing out of the one of the electrodes of the first capacitor element 204. As a result, it is possible to reduce a fluctuation in the potential of the gate electrode 301 of the driving transistor 202 connected to the one of the electrodes of the first capacitor element 204. The potential of the one of the electrodes of the first capacitor element 204 is the potential of the gate electrode 301 of the driving transistor 202 and is a potential that influences the light emission luminance of the light-emitting element 201. Thus, if a fluctuation in the potential of the one of the electrodes of the first capacitor element 204 is reduced, a fluctuation in the light emission luminance is reduced. A fluctuation in the light emission luminance is reduced, whereby it is possible to provide a display apparatus having a high display quality.

FIG. 5B is a variation of the light-emitting device according to the present exemplary embodiment. In this variation, a configuration is employed in which the silicide layer 405 is provided in neither of the driving transistor 202 and the writing transistor 203.

That is, in a cross section perpendicular to the first surface of the silicon substrate 408, the light-emitting device includes a region where the silicide layer 405 is not provided between any of the components of the source 302, the drain 303, and the gate electrode 301 of the driving transistor 202 and the source 305, the drain 306, and the gate electrode 304 of the writing transistor 203 and the insulating layer 406.

With this configuration, the resistance of the peripheral circuit transistor 308 is lowered, and it is also possible to reduce leakage currents in both the driving transistor 202 and the writing transistor 203.

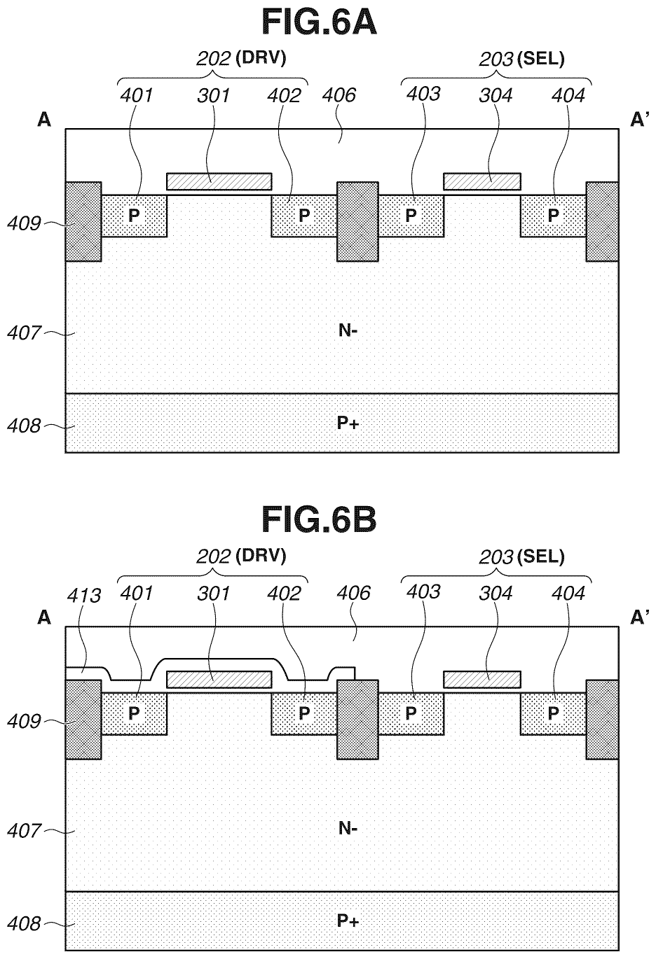

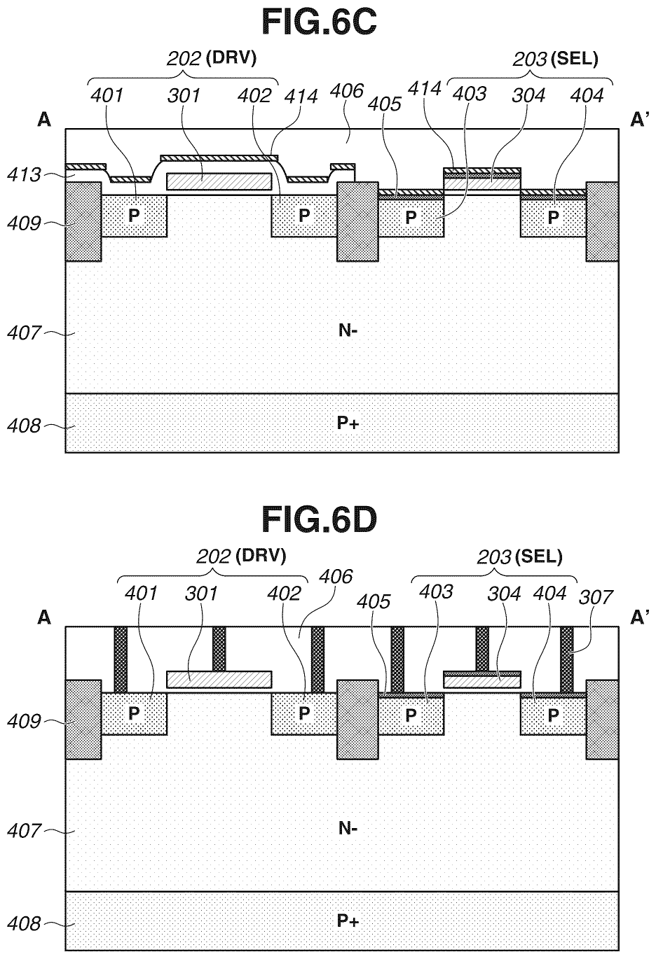

FIGS. 6A to 6D are schematic diagrams illustrating an example of a manufacturing process for the light-emitting device according to each of the above exemplary embodiments.

FIG. 6B illustrates a configuration in which an insulating layer 413 is formed to cover the driving transistor 202 and the writing transistor 203. The method for forming the insulating layer 413 may be a sputtering method, an atom deposition method, or a vapor deposition method such as chemical vapor deposition (CVD).

Next, the insulating layer 413 is partially removed. Specifically, the insulating layer 413 is removed so that at least either the driving transistor 202 or the writing transistor 203 is exposed through the insulating layer 413.

FIG. 6B is a cross-sectional view illustrating a configuration in which the insulating layer 413 is removed to expose the writing transistor 203. A known technique such as etching can be used to expose the writing transistor 203. Although in the present exemplary embodiment, the step of forming the insulating layer 413 on the entire surface and then exposing the writing transistor 203 is described, the step of selectively disposing the insulating layer 413 on the driving transistor 202 may be performed.

FIG. 6C is a cross-sectional view illustrating a configuration in which a metal layer 414 is disposed on the insulating layer 413 and the writing transistor 203. The metal layer 414 is formed to cover the driving transistor 202 and the writing transistor 203 and then is heated, thereby forming the silicide layer 405. Since the driving transistor 202 is covered by the insulating layer 413, the silicon substrate of the driving transistor portion and the metal layer 414 are not in contact with each other. As a result, the silicide layer 405 is not formed in the driving transistor 202. This step of disposing the silicide layer 405 in a portion other than a portion where the insulating layer 413 is formed is the salicide process. The silicide layer 405 formed by the salicide process is a salicide structure in the specification.

FIG. 6D is a cross-sectional view of an example of the light-emitting device after the silicide layer 405 is formed. After the silicide layer 405 is formed, the metal layer 414 is selectively removed. Although the metal layer 414 is removed, the silicide layer 405 formed on the writing transistor 203 is not removed. Then, the insulating layer 406 is formed. In the present exemplary embodiment, the same material as that of the insulating layer 413 is used, and therefore, the boundary between the insulating layers 413 and 406 is not illustrated. After the insulating layer 406 is formed, openings for forming the contact electrodes 307 are formed, and connections between the source 302, the drain 303, and the gate electrode 301 of the driving transistor 202 and the source 305, the drain 306, and the gate electrode 304 of the writing transistor 203 and the contact electrodes 307 are formed. The openings are also occasionally termed vias. First openings for the contact electrodes 307 that come into contact with the writing transistor 203 overlap the silicide layer 405 or the salicide structure in a planar view of the silicon substrate. Second openings for the contact electrodes 307 that come into contact with the driving transistor 202 do not overlap the silicide layer 405 or the salicide structure in the planar view of the silicon substrate. The first and second openings may have opposite configurations depending on the embodiment.

By the above process, it is possible to manufacture an example of the light-emitting device according to the present exemplary embodiment. By the salicide process, a silicide layer is formed in the peripheral circuit transistor 308. The thus configured light-emitting device according to the present exemplary embodiment has a configuration in which the light-emitting device includes a salicide structure in at least any one of the source 310, the drain 311, or the gate electrode 309 of the peripheral circuit transistor 308, and does not include a salicide structure in at least any one of the source 302, the drain 303, or the gate electrode 301 of the driving transistor 202.

Although in the present exemplary embodiment, a configuration has been described in which the silicide layer 405 is provided in the source 305, the drain 306, and the gate electrode 304 of the writing transistor 203, and the silicide layer 405 is not provided in the source 302, the drain 303, and the gate electrode 301 of the driving transistor 202, a configuration can also be employed in which the silicide layer 405 is not provided in the source 305, the drain 306, and the gate electrode 304 of the writing transistor 203. A configuration can also be employed in which the silicide layer 405 is provided in neither of the driving transistor 202 and the writing transistor 203.

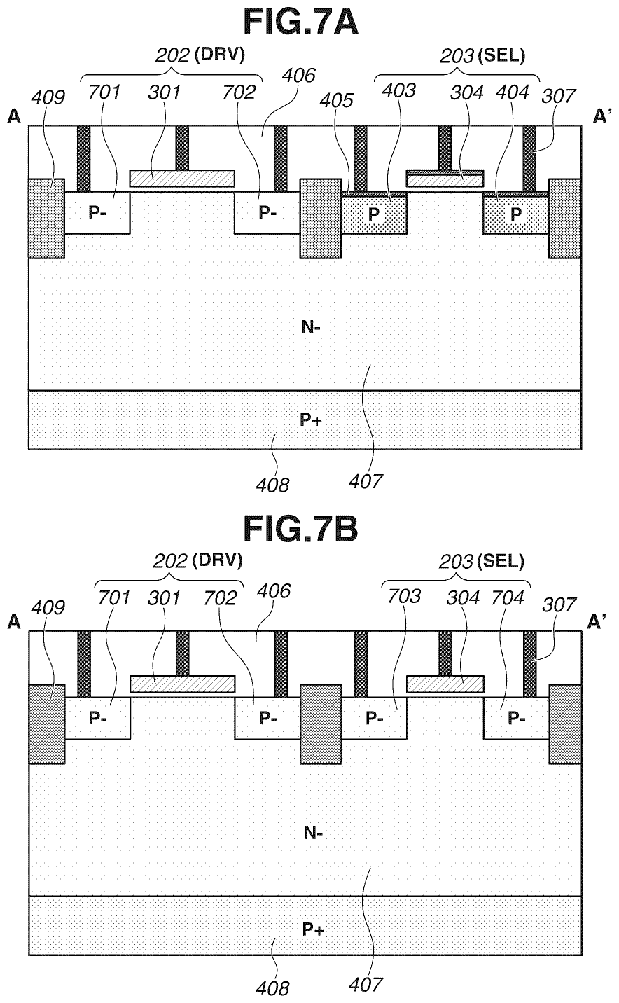

FIG. 7A is a cross-sectional view of a light-emitting device according to a third exemplary embodiment along A-A′ illustrated in FIG. 3A. The light-emitting device according to the present exemplary embodiment is similar to that according to the first exemplary embodiment, except that the light-emitting device according to the present exemplary embodiment has a configuration in which the source 302 and the drain 303 of the driving transistor 202 are low-concentration P-type diffusion layers. Configurations different from those in other exemplary embodiments are mainly described below.

The source 302 and the drain 303 of the driving transistor 202 of the light-emitting device according to the present exemplary embodiment are formed by low-concentration P-type diffusion layers 701 and 702, respectively. The low-concentration P-type diffusion layers 701 and 702 have concentration distributions having concentration peaks in a direction from the source 302 to the drain 303. The peak concentrations of the low-concentration P-type diffusion layers 701 and 702 are lower than the peak concentrations of the P-type diffusion layers 410 and 411 of the peripheral circuit transistor 308. Each peak concentration indicates the concentration at the concentration peak.

That is, the impurity concentration of a diffusion region of the source 302 of the driving transistor 202 and the impurity concentration of a diffusion region of the drain 303 of the driving transistor 202 have concentration distributions having peak concentrations in a first direction from the source 302 to the drain 303. The impurity concentration of a diffusion region of the source 310 of the peripheral circuit transistor 308 and the impurity concentration of a diffusion region of the drain 311 of the peripheral circuit transistor 308 have concentration distributions having peak concentrations in a second direction from the source 310 to the drain 311.

A configuration is employed in which the peak concentration of impurities in the diffusion region of the source 302 or the drain 303 of the driving transistor 202 is smaller than the peak concentration of impurities in the diffusion region of the source 310 or the drain 311 of the peripheral circuit transistor 308.

According to this configuration, it is possible to reduce the electric field intensity between the source 302 and the drain 303 of the driving transistor 202 and the N-type well layer 407, and it is possible to reduce a leakage current flowing from the well into the source 302 and the drain 303. This can also reduce a leakage current flowing from the driving transistor 202 into the organic light-emitting element 201. Thus, it is possible to display high-quality black.

The present exemplary embodiment has illustrated a configuration in which the peak concentration of impurities in the driving transistor 202 is smaller than the peak concentration of impurities in the peripheral circuit transistor 308. The present disclosure is not limited to this. A configuration may be employed in which the peak concentration of impurities in another transistor is smaller than the peak concentration of impurities in the peripheral circuit transistor 308.

FIG. 7B is a cross-sectional view of a light-emitting device according to a fourth exemplary embodiment along A-A′ illustrated in FIG. 3A. In the present exemplary embodiment, a configuration is employed in which the source 305 and the drain 306 of the writing transistor 203 are low-concentration P-type diffusion layers, and a semiconductor compound layer is not placed. Configurations different from those in other exemplary embodiments are mainly described below.

The source 305 and the drain 306 of the writing transistor 203 are formed by low-concentration P-type diffusion layers 703 and 704, respectively. The low-concentration P-type diffusion layers 703 and 704 have concentration distributions having peak concentrations in a direction from the source 305 to the drain 306. The peak concentrations of the low-concentration P-type diffusion layers 703 and 704 are lower than the peak concentrations of the P-type diffusion layers 410 and 411 of the peripheral circuit transistor 308.

That is, the impurity concentration of a diffusion region of the source 305 of the writing transistor 203 and the impurity concentration of a diffusion region of the drain 306 of the writing transistor 203 have concentration distributions having concentration peaks in a third direction from the source 305 to the drain 306. The impurity concentration of the diffusion region of the source 310 of the peripheral circuit transistor 308 and the impurity concentration of the diffusion region of the drain 311 of the peripheral circuit transistor 308 have concentration distributions having concentration peaks in the second direction from the source 310 to the drain 311. The peak concentration of impurities in the diffusion region of the source 305 or the drain 306 of the writing transistor 203 is smaller than the peak concentration of impurities in the diffusion region of the source 310 or the drain 311 of the peripheral circuit transistor 308. Each peak concentration indicates the concentration at the concentration peak.

According to this configuration, it is possible to reduce the electric field intensity between the source 305 and the drain 306 of the writing transistor 203 and the N-type well layer 407, and it is possible to reduce a leakage current flowing from the well into the source 305 and the drain 306. This can also reduce a leakage current flowing into the first capacitor element 204. Thus, it is possible to reduce a fluctuation in a luminance signal held in the first capacitor element 204. Thus, the organic light-emitting element 201 can stably emit light at a predetermined luminance.

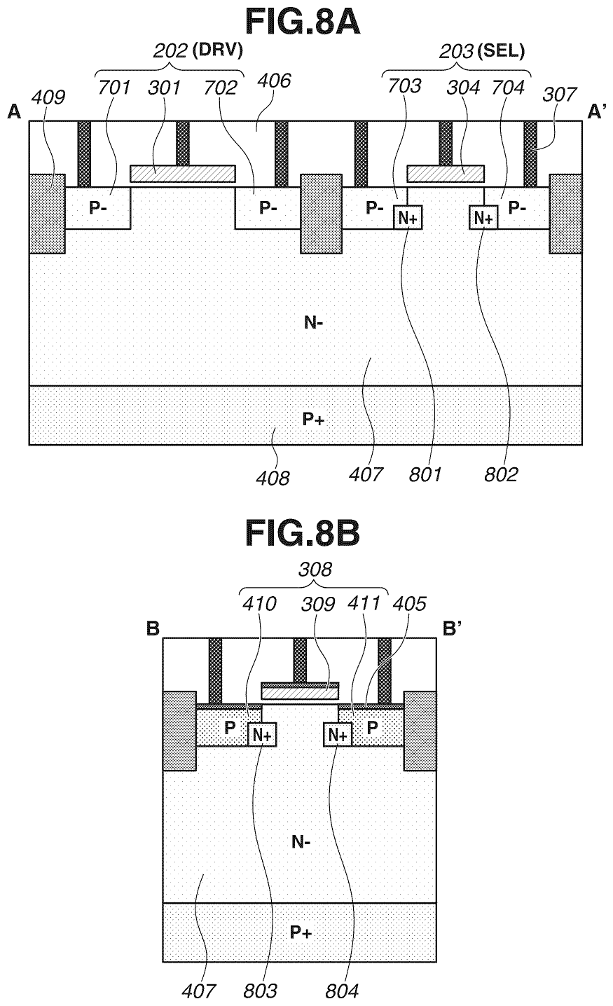

FIG. 8A is a cross-sectional view of a light-emitting device according to a fifth exemplary embodiment along A-A′ illustrated in FIG. 3A. In the present exemplary embodiment, a configuration is employed in which the writing transistor 203 and the peripheral circuit transistor 308 include halo structures. Configurations different from those in other exemplary embodiments are mainly described below.

In the writing transistor 203, high-concentration N-type diffusion layers 801 and 802 that are halo injection layers are adjacent to the low-concentration P-type diffusion layers 703 and 704, respectively. The N-type well layer 407 having a lower concentration is disposed between the high-concentration N-type diffusion layers 801 and 802.

The driving transistor 202 according to the present exemplary embodiment has a structure where halo injection layers are not placed. Since the driving transistor 202 supplies a subthreshold current to the organic light-emitting element 201, if halo injection layers are placed in the driving transistor 202, the subthreshold current greatly varies with respect to each pixel 102 even if variation in the concentrations of the halo injection layers is small. Halo injection layers are not placed, whereby it is possible to reduce variation in the amount of current supplied from the driving transistor 202 to the organic light-emitting element 201.

FIG. 8B is a cross-sectional view of the light-emitting device according to the present exemplary embodiment along B-B′ illustrated in FIG. 3B. As illustrated in FIG. 8B, in the peripheral circuit transistor 308, N-type diffusion layers 803 and 804 that are halo injection layers are adjacent to the P-type diffusion layers 410 and 411, respectively. The N-type well layer 407 having a lower concentration is disposed between the N-type diffusion layers 803 and 804. The present exemplary embodiment illustrates a configuration in which the peak concentrations of the high-concentration N-type diffusion layers 801 and 802 constituting the writing transistor 203 are higher than the peak concentrations of the N-type diffusion layers 803 and 804 constituting the peripheral circuit transistor 308. The present disclosure, however, is not limited to this. The concentrations of the halo injection layers may be appropriately adjusted according to the amount of a leakage current, and the relative magnitude relationship may be reversed.

In the light-emitting device according to the present exemplary embodiment, the writing transistor 203 includes halo injection layers in the diffusion regions of the source 305 and the drain 306, and the halo injection layers have a polarity opposite to the polarity of the diffusion regions. That is, the halo injection layers have the same polarity as the polarity of a channel formed when the transistor is on.

Then, the peripheral circuit transistor 308 includes halo injection layers in the diffusion regions of the source 310 and the drain 311, and the halo injection layers have a polarity opposite to the polarity of the diffusion regions.

A configuration is employed in which the peak concentrations of the impurity concentrations of the halo injection layers of the writing transistor 203 are higher than the peak concentrations of the impurity concentrations of the halo injection layers of the peripheral circuit transistor 308. Although in the present exemplary embodiment, the relationship between the peak concentrations is configured as described above, the peak concentrations of the impurity concentrations of the halo injection layers of the writing transistor 203 may only need to be different from the peak concentrations of the impurity concentrations of the halo injection layers of the peripheral circuit transistor 308. It is possible to adjust the peak concentrations of the impurity concentrations by adjusting control of a leakage current.

According to this configuration, it is possible to reduce a leakage current flowing from the source 305 to the drain 306 of the writing transistor 203 and into the first capacitor element 204. Thus, it is possible to prevent a fluctuation in a luminance signal held in the first capacitor element 204. Thus, the organic light-emitting element 201 can stably emit light at a predetermined luminance. It is also possible to reduce a leakage current flowing from the source 310 of the peripheral circuit transistor 308 into the drain 311 of the peripheral circuit transistor 308. Thus, it is possible to reduce a consumption current in the peripheral circuit unit.

In a sixth exemplary embodiment, a light-emitting device includes a light emission control transistor disposed between a power supply that supplies a current to a light-emitting element and a driving transistor. More specifically, a configuration is employed in which the light-emitting device includes a light emission control transistor 1001 that controls the supply of a current from the first power supply terminal 205 (Vdd) to the driving transistor 202. Configurations different from those in other exemplary embodiments are mainly described below. The light emission control transistor is also referred to as a “fourth transistor” following the driving transistor 202, the writing transistor 203, and the peripheral circuit transistor 308.

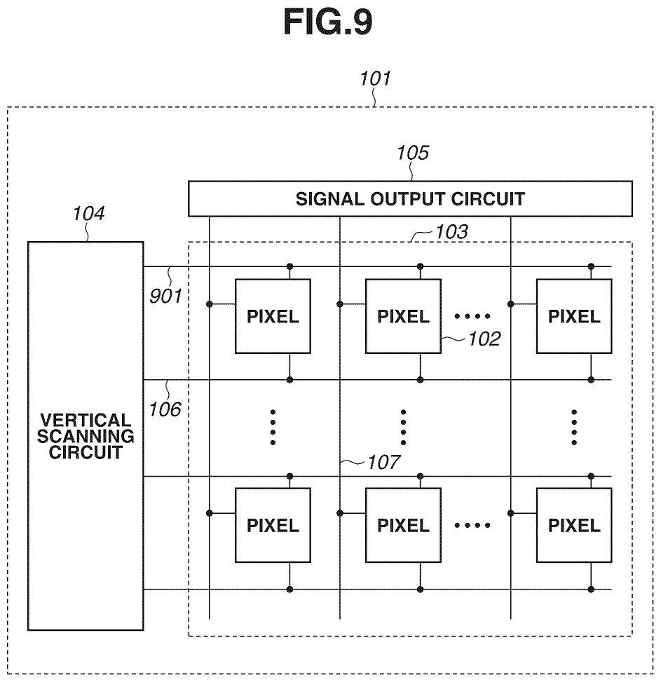

FIG. 9 is a schematic diagram illustrating an example of the light-emitting device according to the present exemplary embodiment. In the pixel array unit 103, a second scanning line 901 is disposed with respect to each pixel row along the row direction. The second scanning line 901 is connected to the output end of a corresponding row of the vertical scanning circuit 104 and supplies a light emission control signal to each pixel 102.

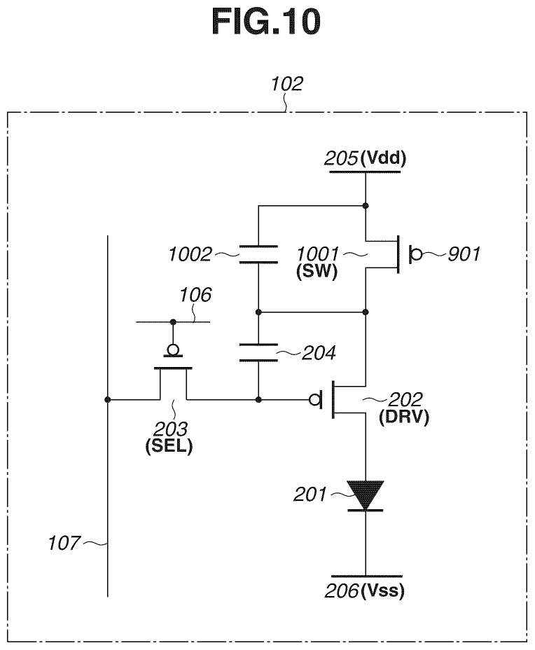

FIG. 10 is a circuit diagram illustrating an example of a pixel circuit included in the light-emitting device 101 in FIG. 9. One of the source and the drain (the drain in this case) of a light emission control transistor 1001 is connected to one of the source and the drain (the source in this case) of the driving transistor 202. The other (the source in this case) of the light emission control transistor 1001 is connected to the first power supply terminal 205 (Vdd). The gate of the light emission control transistor 1001 is connected to the second scanning line 901.

A second capacitor element 1002 is connected between the drain of the light emission control transistor 1001 and the first power supply terminal 205 (Vdd). The second capacitor element 1002 may be any of a parasitic capacitor, a gate-channel capacitor of a MOS, a MIM structure, and a MOM structure.

The light emission control transistor 1001 responds to a light emission control signal applied from the vertical scanning circuit 104 to the gate of the light emission control transistor 1001 via the second scanning line 901 and enters an on state, thereby allowing the supply of a current from the first power supply terminal 205 (Vdd) to the driving transistor 202. This enables the organic light-emitting element 201 to emit light using the driving transistor 202. That is, the light emission control transistor 1001 has a function as a transistor that controls the light emission and non-light emission of the organic light-emitting element 201. In this manner, by a switching operation of the light emission control transistor 1001, it is possible to perform so-called duty control in which the ratio between the light emission period and the non-light emission period of the organic light-emitting element 201 can be controlled. By the duty control, it is possible to reduce an afterimage blur according to the emission of light from the pixel 102 for one frame period. Particularly, it is possible to improve the image quality of a moving image.

Due to variation in manufacturing, a threshold for the driving transistor 202 may differ with respect to each pixel 102. In a case where the same signal voltage is written to a plurality of pixels 102 of the same light emission color, the amount of current flowing through the driving transistor 202 differs with respect to each pixel 102, and the amount of light emission varies. Accordingly, before the signal voltage is written, a so-called threshold correction operation for holding the threshold between the gate 301 and the source 302 of the driving transistor 202 is performed. By the threshold correction operation, it is possible to reduce variation in the amount of current of the driving transistor 202 with respect to each pixel 102. Thus, it is possible to achieve more uniform light emission.

In the threshold correction operation, after a current is applied to the organic light-emitting element 201 via the light emission control transistor 1001 and the driving transistor 202, the light emission control transistor 1001 is brought into an off state. Consequently, a current flows to the organic light-emitting element 201 and the threshold is corrected until the voltage between the gate 301 and the source 302 of the driving transistor 202 stabilizes.

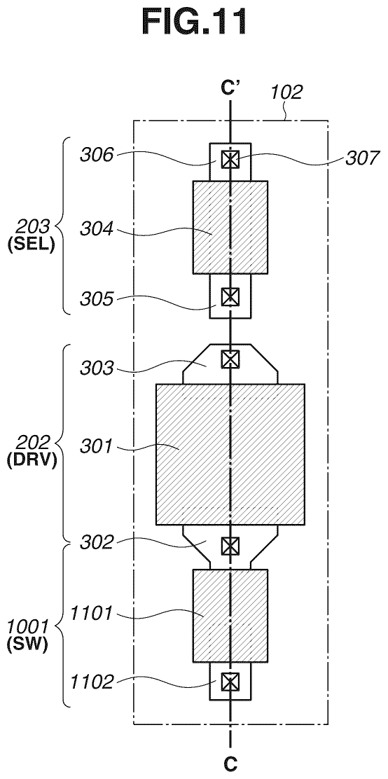

FIG. 11 is a plan view of an example of the circuit illustrated in FIG. 10. The light emission control transistor 1001 includes a gate electrode 1101, a source portion 1102, and a drain portion 302.

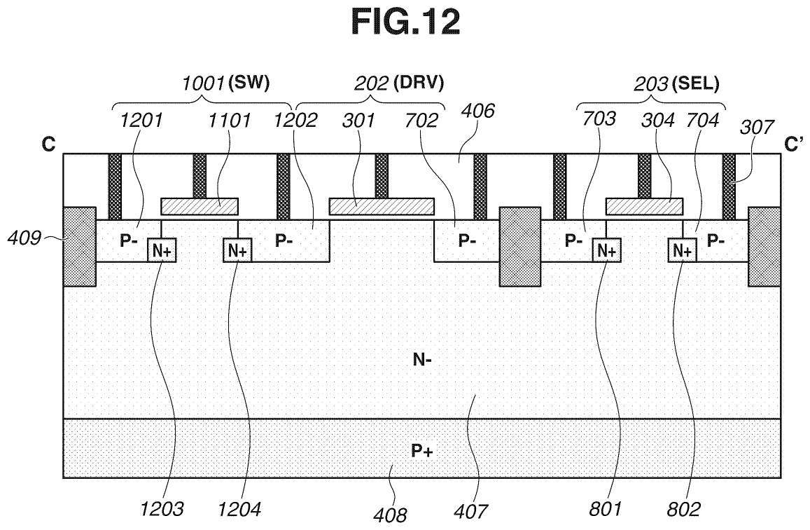

FIG. 12 is a cross-sectional view along C-C′ in the plan view illustrated in FIG. 11. The source portion 1102 and the drain portion 302 of the light emission control transistor 1001 are formed by low-concentration P-type diffusion layers 1201 and 1202, respectively. The peak concentrations of the low-concentration P-type diffusion layers 1201 and 1202 are lower than the peak concentrations of the P-type diffusion layers 410 and 411 of the peripheral circuit transistor 308. High-concentration N-type diffusion layers 1203 and 1204 that are halo injection layers are adjacent to the low-concentration P-type diffusion layers 1201 and 1202, respectively. The N-type well layer 407 having a lower concentration is disposed between the high-concentration N-type diffusion layers 1203 and 1204. The present exemplary embodiment illustrates a configuration in which the peak concentrations of the high-concentration N-type diffusion layers 1203 and 1204 constituting the light emission control transistor 1001 are higher than the peak concentrations of the N-type diffusion layers 803 and 804 constituting the peripheral circuit transistor 308. The present disclosure, however, is not limited to this. The concentrations of the halo injection layers may be appropriately adjusted according to the amount of a leakage current, and the relative magnitude relationship may be reversed. The concentrations of the halo injection layers of the light emission control transistor 1001 may be the same as those of the halo injection layers of the writing transistor 203. In the specification, “the same” includes being substantially the same in consideration of a manufacturing error.

The present exemplary embodiment has illustrated a configuration in which the light-emitting device includes the light emission control transistor 1001 disposed between the power supply 205 that supplies a current to the light-emitting element 201 and the driving transistor 202, and the halo injection layers are provided. The present disclosure is not limited to this. A configuration may be employed in which the light-emitting device includes a region where a silicide layer is not provided between at least any one of the source 1102, the drain 302, or the gate electrode 1101 of the light emission control transistor 1001 and the insulating layer 406. A configuration may be employed in which the light-emitting device does not include a salicide structure in at least any one of the source 1102, the drain 302, or the gate electrode 1101 of the light emission control transistor 1001.

A configuration may be employed in which the impurity concentration of a diffusion region of the source 1102 of the light emission control transistor 1001 and the impurity concentration of a diffusion region of the drain 302 have concentration distributions having concentration peaks in a fourth direction from the source 1102 to the drain 302, the impurity concentration of the diffusion region of the source 310 of the peripheral circuit transistor 308 and the impurity concentration of the diffusion region of the drain 311 of the peripheral circuit transistor 308 have concentration distributions having concentration peaks in the second direction from the source 310 to the drain 311, and the peak concentration of impurities in the diffusion region of the source 1102 or the drain 302 of the light emission control transistor 1001 is smaller than the peak concentration of impurities in the diffusion region of the source 310 or the drain 311 of the peripheral circuit transistor 308.

According to this configuration, when a threshold is corrected, it is possible to reduce a leakage current flowing from the source 1102 to the drain 302 of the light emission control transistor 1001 and into the first capacitor element 204. Thus, it is possible to reduce a fluctuation in a threshold voltage held in the first capacitor element 204.

A light-emitting device according to a seventh exemplary embodiment includes a reset transistor disposed between a terminal connected to the light-emitting element 201 between the drain 303 and the source 302 of the driving transistor 202, and a terminal having a potential lower than that of the power supply 205 that supplies a current to the light-emitting element 201. More specifically, a configuration is employed in which the light-emitting device includes a reset transistor 1401 that resets the light-emitting element 201 by connecting the anode of the light-emitting element 201 to a third power supply terminal 1402 (hereinafter, “Vres”). The reset transistor is also referred to as a “fifth transistor” following the light emission control transistor 1001. The third power supply terminal 1402 may be a power supply having a potential lower than that of the power supply 205 that supplies a current to the light-emitting element 201. The third power supply terminal 1402 according to the present exemplary embodiment may only need to have a potential for the reset transistor 1401 to reset the light-emitting element 201, and is not limited to the present exemplary embodiment. Configurations different from those in other exemplary embodiments are mainly described below.

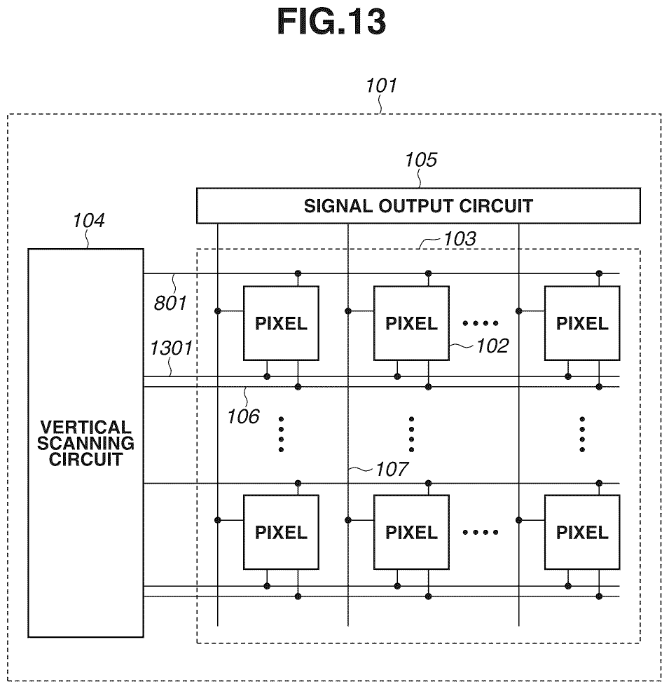

FIG. 13 is a schematic diagram illustrating an example of the light-emitting device according to the present exemplary embodiment. In the pixel array unit 103, a third scanning line 1301 is disposed with respect to each pixel row along the row direction. The third scanning line 1301 is connected to the output end of a corresponding row of the vertical scanning circuit 104 and supplies a reset signal to each pixel 102.

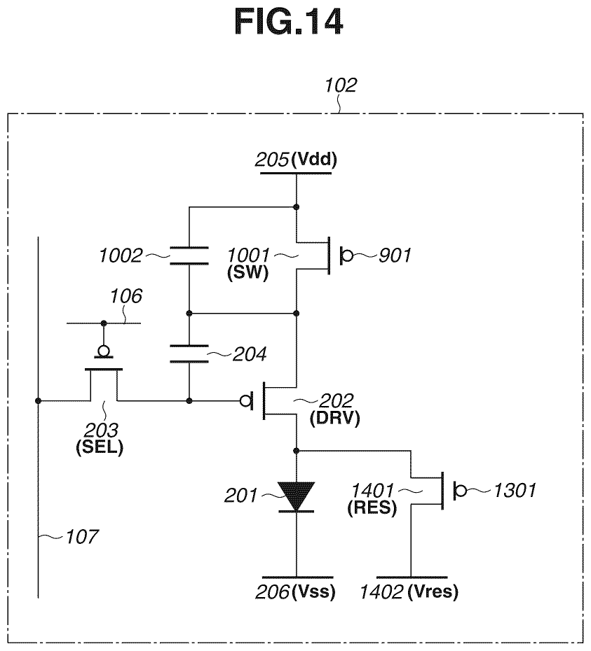

FIG. 14 is a circuit diagram illustrating an example of a pixel circuit included in the light-emitting device 101 in FIG. 13. One of the source and the drain (the source in this case) of a reset transistor 1401 is connected to one of the source and the drain (the drain in this case) of the driving transistor 202. The other of the reset transistor 1401 is connected to a third power supply terminal 1402 (Vres). The gate of the reset transistor 1401 is connected to the third scanning line 1301. By bringing the reset transistor 1401 into an on state, it is possible to connect the anode of the organic light-emitting element 201 to the third power supply terminal 1402 (Vres) and set the luminance of the organic light-emitting element 201 to a black level. Consequently, it is possible to achieve a light-emitting device having high contrast. During a light emission period, the reset transistor 1401 is in an off state.

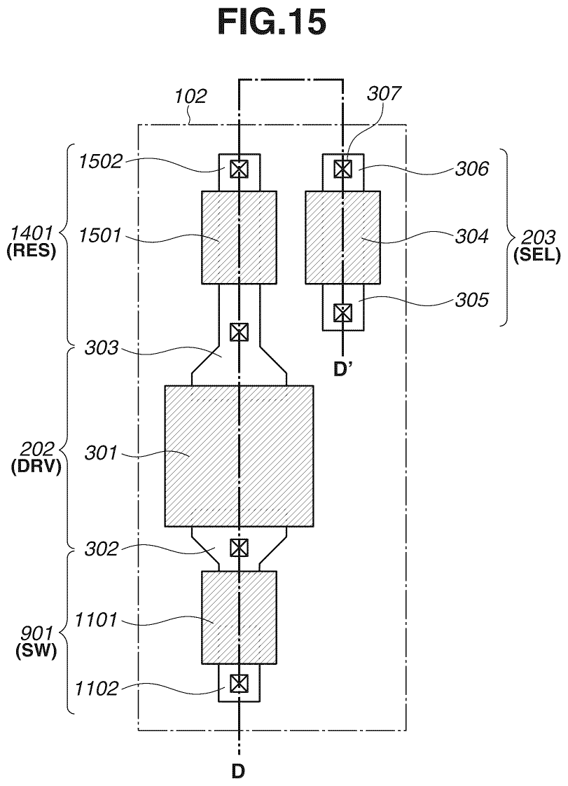

FIG. 15 is a plan view of an example of the circuit illustrated in FIG. 14. The reset transistor 1401 includes a gate electrode 1501, a source 303, and a drain 1502. The source node of the reset transistor 1401 is the same as the drain node of the drive transistor 202, and then, the same reference numeral 303 is used.

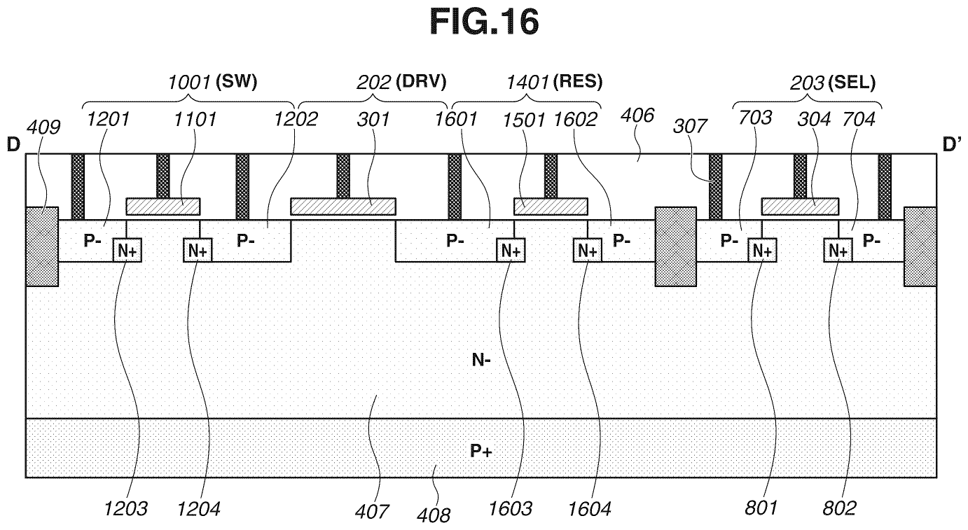

FIG. 16 is a cross-sectional view along D-D′ in the plan view illustrated in FIG. 15. The source 303 and the drain 1502 of the reset transistor 1401 are formed by low-concentration P-type diffusion layers 1601 and 1602, respectively. The peak concentrations of the low-concentration P-type diffusion layers 1601 and 1602 are lower than the peak concentrations of the P-type diffusion layers 410 and 411 of the peripheral circuit transistor 308. High-concentration N-type diffusion layers 1603 and 1604 that are halo injection layers are adjacent to the low-concentration P-type diffusion layers 1601 and 1602, respectively. The N-type well layer 407 having a lower concentration is disposed between the high-concentration N-type diffusion layers 1603 and 1604. The present exemplary embodiment illustrates a configuration in which the peak concentrations of the high-concentration N-type diffusion layers 1603 and 1604 constituting the reset transistor 1401 are higher than the peak concentrations of the N-type diffusion layers 803 and 804 constituting the peripheral circuit transistor 308. The present disclosure, however, is not limited to this. The concentrations of the halo injection layers may be appropriately adjusted according to the amount of a leakage current, and the relative magnitude relationship may be reversed. The concentrations of the halo injection layers of the reset transistor 1401 may be the same as those of the halo injection layers of the writing transistor 203.

The light-emitting device according to the present exemplary embodiment includes the reset transistor 1401 disposed between a terminal connected to the light-emitting element 201 between the drain 303 and the source 302 of the driving transistor 202, and a terminal having a potential lower than that of the power supply 205 that supplies a current to the light-emitting element 201.

A configuration may be employed in which the reset transistor according to the present exemplary embodiment includes a region where a silicide layer is not provided between at least any one of the source 303, the drain 1502, or the gate electrode 1501 of the reset transistor 1401 and the insulating layer 406 as in the configurations of the other exemplary embodiments. A configuration may be employed in which the reset transistor does not include a salicide structure in at least any one of the source 303, the drain 1502, or the gate electrode 1501 of the reset transistor 1401.

In the reset transistor according to the present exemplary embodiment, a configuration may be employed in which the impurity concentration of a diffusion region of the source 303 of the reset transistor 1401 and the impurity concentration of a diffusion region of the drain 1502 have concentration distributions having concentration peaks in a fifth direction from the source 303 to the drain 1502, the impurity concentration of the diffusion region of the source 310 of the peripheral circuit transistor 308 and the impurity concentration of the diffusion region of the drain 311 of the peripheral circuit transistor 308 have concentration distributions having concentration peaks in the second direction from the source 310 to the drain 311, and the peak concentration of impurities in the diffusion region of the source 303 or the drain 1502 of the reset transistor 1401 is smaller than the peak concentration of impurities in the diffusion region of the source 310 or the drain 311 of the peripheral circuit transistor 308. Each peak concentration indicates the concentration at the concentration peak.

According to this configuration, it is possible to reduce a leakage current flowing from the source 303 of the reset transistor 1401 into the drain 1502 of the reset transistor 1401. This can reduce a leakage current flowing from the driving transistor 202 into the third power supply terminal 1402 (Vres) via the reset transistor 1401 during a light emission period. Thus, it is possible to reduce a consumption current in the pixel 102.

A light-emitting device according to an eighth exemplary embodiment has a configuration in which transistors constituting an inverter circuit 1701 in the vertical scanning circuit 104 include halo structures. Configurations different from those in other exemplary embodiments are mainly described below.

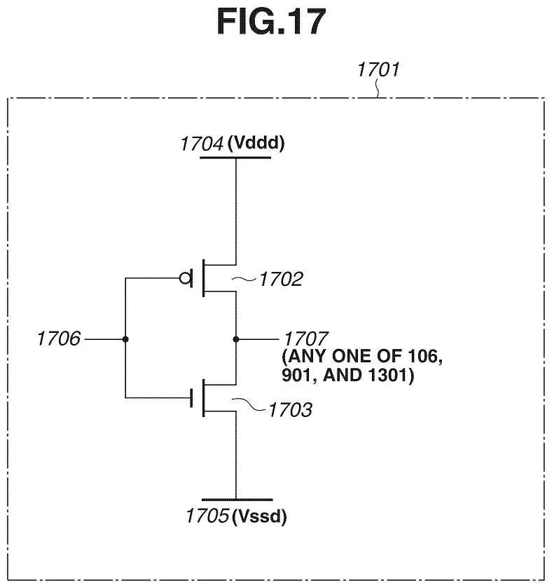

FIG. 17 is a circuit diagram of an example of an inverter circuit 1701 in the vertical scanning circuit 104 included in the light-emitting device 101 in FIG. 13. The drain, the source, and the gate of a P-type transistor 1702 are connected to the drain of an N-type transistor 1703, a fourth power supply terminal 1704 (hereinafter, “Vddd”), and the gate of the N-type transistor 1703, respectively.

The source of the N-type transistor 1703 is connected to a fifth power supply terminal 1705 (hereinafter, “Vssd”).

The inverter circuit 1701 includes an input terminal 1706 and an output terminal 1707. The input terminal 1706 is connected to the gates of the P-type transistor 1702 and the N-type transistor 1703. The output terminal 1707 is connected to the drain of the P-type transistor 1702, the drain of the N-type transistor 1703, and further, any of the first scanning line 106, the second scanning line 901, and the third scanning line 1301.

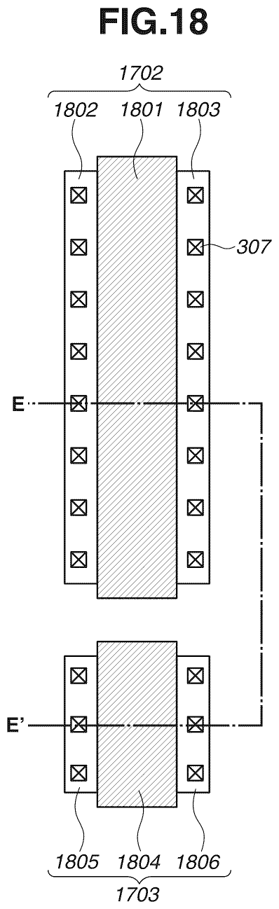

FIG. 18 is a plan view of an example of the circuit illustrated in FIG. 17. The P-type transistor 1702 includes a gate electrode 1801, a source 1802, and a drain 1803.

The N-type transistor 1703 includes a gate electrode 1804, a source 1805, and a drain 1806.

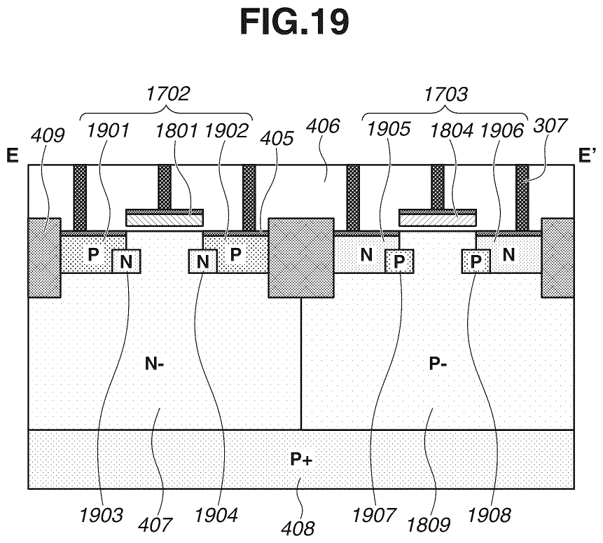

FIG. 19 is a cross-sectional view along E-E′ in the plan view illustrated in FIG. 18. The source 1802 and the drain 1803 of the P-type transistor 1702 are formed by P-type diffusion layers 1901 and 1902, respectively.

N-type diffusion layers 1903 and 1904 that are halo injection layers are adjacent to the P-type diffusion layers 1901 and 1902, respectively. The N-type well layer 407 having a lower concentration is disposed between the N-type diffusion layers 1903 and 1904.

The drain 1806 and the source 1805 of the N-type peripheral circuit transistor 1703 are formed by N-type diffusion layers 1905 and 1906, respectively. P-type diffusion layers 1907 and 1908 that are halo injection layers are adjacent to the N-type diffusion layers 1905 and 1906, respectively. A P-type well layer 1809 having a lower concentration is disposed between the P-type diffusion layers 1907 and 1908.

According to this configuration, it is possible to reduce a leakage current flowing from the fourth power supply terminal 1704 (Vddd) into the fifth power supply terminal 1705 (Vssd) via the P-type peripheral circuit transistor 1702 and the N-type peripheral circuit transistor 1703. Thus, it is possible to reduce a consumption current in the vertical scanning circuit 104.

### Other Exemplary Embodiments

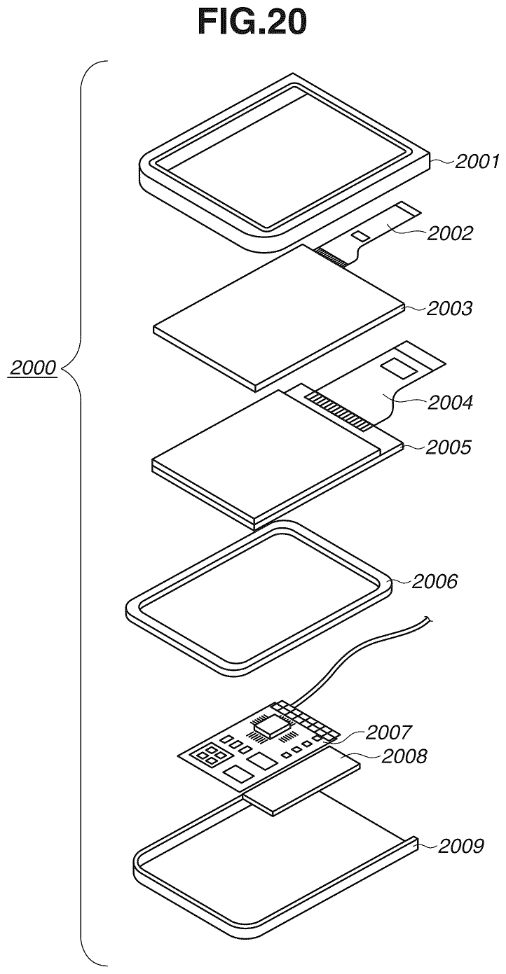

FIG. 20 is a schematic diagram illustrating an example of a display apparatus according to the present exemplary embodiment. A display apparatus 2000 may include a touch panel 2003, a display panel 2005, a frame 2006, a circuit substrate 2007, and a battery 2008 between an upper cover 2001 and a lower cover 2009. The touch panel 2003 and the display panel 2005 are connected to flexible printed circuits (FPCs) 2002 and 2004, respectively. On the circuit substrate 2007, a transistor is printed. The battery 2008 may not be provided unless the display apparatus 2000 is a mobile device, or may be provided at another position even if the display apparatus 2000 is a mobile device.

The display apparatus according to the present exemplary embodiment may include color filters having red, green, and blue colors. In the color filters, the red, green, and blue colors may be arranged in the delta arrangement.

The display apparatus according to the present exemplary embodiment may also be used in a display unit of a mobile terminal. At this time, the display apparatus may have both a display function and an operation function. Examples of the mobile terminal include a mobile phone such as a smartphone, a tablet, and a head-mounted display.

The display apparatus according to the present exemplary embodiment may also be used in a display unit of an imaging apparatus including an optical unit that includes a plurality of lenses, and an imaging element that receives light passing through the optical unit. The imaging apparatus may include a display unit that displays information acquired by the imaging element. The display unit may be a display unit exposed to outside the imaging apparatus, or may be a display unit placed in a viewfinder. The imaging apparatus may be a digital camera or a digital video camera.

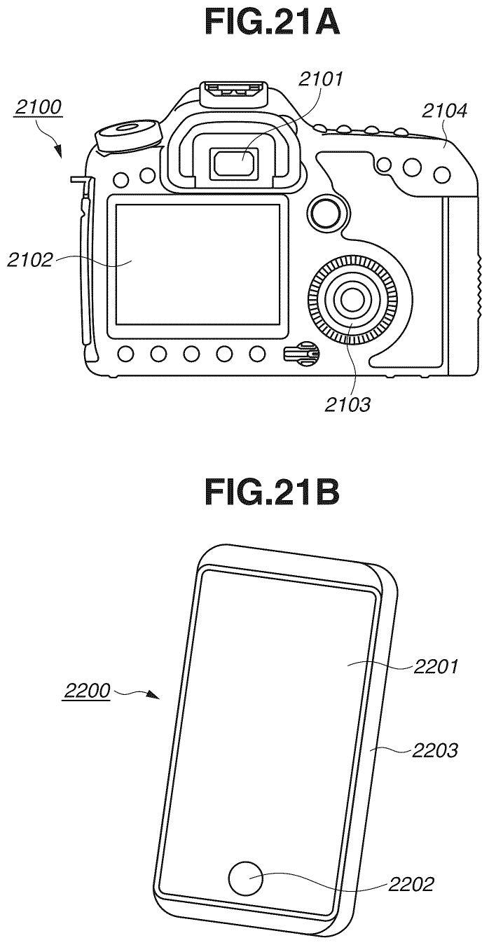

FIG. 21A is a schematic diagram illustrating an example of an imaging apparatus according to the present exemplary embodiment. An imaging apparatus 2100 may include a viewfinder 2101, a back surface display 2102, an operation unit 2103, and a housing 2104. The viewfinder 2101 may include a display apparatus according to the present exemplary embodiment. In this case, the display apparatus may display not only a captured image, but also environment information and an image capturing instruction. The environment information may include the intensity of external light, the direction of external light, the moving speed of an object, and the possibility that an object is blocked by a blocking object.

Since a timing suitable for capturing an image lasts for a short time, the information is to be displayed as soon as possible. Thus, it is desirable to use a display apparatus using the organic light-emitting element according to the present disclosure. This is because the response speed of the organic light-emitting element is fast. The display apparatus using the organic light-emitting element can be used more suitably than these apparatuses and a liquid crystal display apparatus, which require a fast display speed.

The imaging apparatus 2100 includes an optical unit (not illustrated). The optical unit includes a plurality of lenses and forms an image on an imaging element accommodated in the housing 2104. The focus can be adjusted by adjusting the relative positions of the plurality of lenses. This operation can also be performed automatically. The imaging apparatus 2100 may also be referred to as a “photoelectric conversion apparatus”. The photoelectric conversion apparatus can include a method for detecting the difference from the previous image without sequentially capturing images or a method for clipping an image from an always recorded image as an imaging method.

FIG. 21B is a schematic diagram illustrating an example of an electronic device according to the present exemplary embodiment. An electronic device 2200 includes a display unit 2201, an operation unit 2202, and a housing 2203. The housing 2203 may include a circuit, a printed substrate including the circuit, a battery, and a communication unit. The operation unit 2202 may be a button, or may be a response unit using a touch panel method. The operation unit 2202 may be a biometric unit that recognizes a fingerprint and releases a lock. The communication unit is a communication unit that communicates with outside, and may be wired or wireless. The electronic device 2200 including the communication unit can also be said to be a communication device. The electronic device 2200 may further have a camera function by including a lens and an imaging element. An image captured by the camera function is displayed on the display unit 2201.

Examples of the electronic device 2200 include a smartphone and a laptop personal computer.

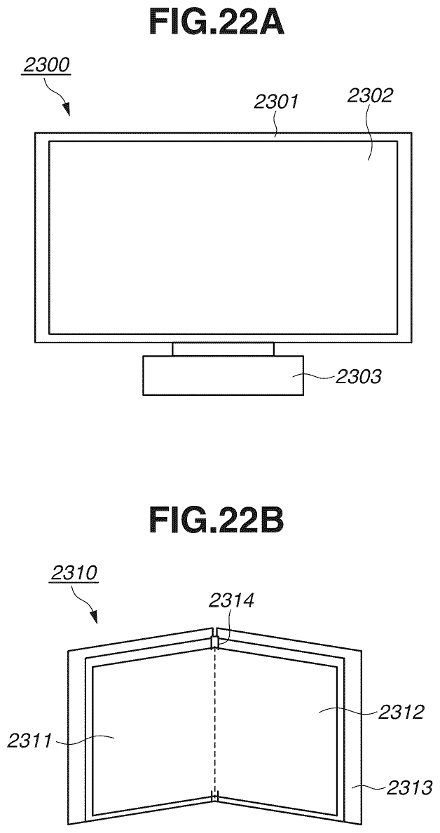

FIGS. 22A and 22B are schematic diagrams illustrating examples of a display apparatus according to the present exemplary embodiment. FIG. 22A illustrates a display apparatus 2300 such as a television monitor or a personal computer (PC) monitor. The display apparatus 2300 includes a frame 2301 and a display unit 2302. A light-emitting device according to the present exemplary embodiment may be used in the display unit 2302.

The display apparatus 2300 includes a base 2303 that supports the frame 2301 and the display unit 2302. The base 2303 is not limited to the form in FIG. 22A. The lower side of the frame 2301 may double as a base.

The frame 2301 and the display unit 2302 may be curved. The radius of curvature of the curve may be 5000 mm or more and 6000 mm or less.

FIG. 22B is a schematic diagram illustrating another example of the display apparatus according to the present exemplary embodiment. A display apparatus 2310 in FIG. 22B is configured to be folded and is a so-called foldable display apparatus. The display apparatus 2310 includes a first display unit 2311, a second display unit 2312, a housing 2313, and a folding point 2314. The first display unit 2311 and the second display unit 2312 may include the light-emitting device according to the present exemplary embodiment. The first display unit 2311 and the second display unit 2312 may be a single display apparatus without a joint. The first display unit 2311 and the second display unit 2312 can be divided at the folding point 2314. The first display unit 2311 and the second display unit 2312 may display images different from each other, or may display a single image.

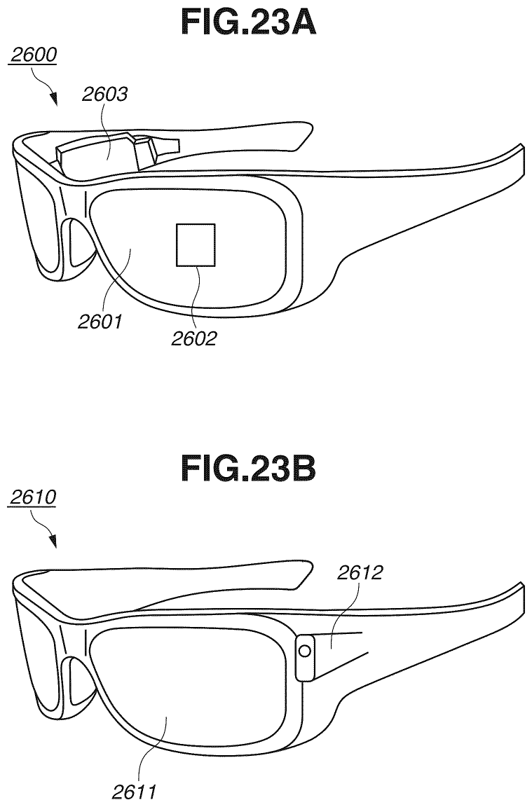

FIGS. 23A and 23B are schematic diagrams illustrating examples of a wearable device according to the present exemplary embodiment. The wearable device can be applied to a system that can be worn as a wearable device such as smartglasses, a head-mounted display (HMD), or smart contact lenses. An imaging display apparatus used in such application examples includes an imaging apparatus capable of photoelectrically converting visible light and a display apparatus capable of emitting visible light.

FIG. 23A illustrates eyeglasses 2600 (smartglasses) according to an application example. On a front surface of a lens 2601 of the eyeglasses 2600, an imaging apparatus 2602 such as a complementary metal-oxide-semiconductor (CMOS) sensor or a single-photon avalanche diode (SPAD) is provided. On a back surface of the lens 2601, the display apparatus according to each of the above exemplary embodiments is provided.

The eyeglasses 2600 further include a control apparatus 2603. The control apparatus 2603 functions as a power supply that supplies power to the imaging apparatus 2602 and the display apparatus according to each of the exemplary embodiments. The control apparatus 2603 controls the operations of the imaging apparatus 2602 and the display apparatus. In the lens 2601, an optical system for collecting light on the imaging apparatus 2602 is formed.

FIG. 23B illustrates eyeglasses 2610 (smartglasses) according to another application example. The eyeglasses 2610 include a control apparatus 2612. On the control apparatus 2612, an imaging apparatus equivalent to the imaging apparatus 2602 and the display apparatus are mounted. In a lens 2611, an optical system for projecting light emitted from the display apparatus in the control apparatus 2612 is formed. An image is projected onto the lens 2611. The control apparatus 2612 functions as a power supply that supplies power to the imaging apparatus and the display apparatus, and also controls the operations of the imaging apparatus and the display apparatus. The control apparatus 2612 includes an image control unit. The image control unit transmits an image control signal to a peripheral circuit of a light-emitting device. The control apparatus 2612 may also include a line-of-sight detection unit that detects the line of sight of a wearer (a user). The line of sight may be detected using infrared light. An infrared light-emitting unit emits infrared light to the eyeball of the user gazing at the display image. An imaging unit including a light-receiving element detects reflected light of the emitted infrared light from the eyeball, thereby obtaining a captured image of the eyeball. The control apparatus 2612 includes a reduction unit that reduces light from the infrared light-emitting unit to a display unit in a planar view, thereby reducing a decrease in the quality of the image.

The line of sight of the user to the display image is detected from the captured image of the eyeball obtained by capturing the infrared light. Any known technique can be applied to the line-of-sight detection using the captured image of the eyeball. As an example, a line-of-sight detection method based on a Purkinje image formed by the reflection of emitted light from the cornea can be used.

More specifically, a line-of-sight detection process based on a pupil-corneal reflection method is performed. Using the pupil-corneal reflection method, a line-of-sight vector indicating the direction (the rotation angle) of the eyeball is calculated based on an image of the pupil and a Purkinje image included in the captured image of the eyeball, thereby detecting the line of sight of the user.

A display apparatus according to an exemplary embodiment of the present disclosure may include an imaging apparatus including a light-receiving element and control a display image on the display apparatus based on line-of-sight information regarding a user from the imaging apparatus.

Specifically, based on the line-of-sight information, the display apparatus determines a first display region gazed at by the user and a second display region other than the first display region. The first and second display regions may be determined by a control apparatus of the display apparatus, or the display apparatus may receive the first and second display regions determined by an external control apparatus. In a display region of the display apparatus, the display resolution of the first display region may be controlled to be higher than the display resolution of the second display region. That is, the resolution of the second display region may be set to be lower than the resolution of the first display region.

The first and second display regions of the display region may be determined based on the line-of-sight information. The display apparatus may determine the first display region and a region having high priority using artificial intelligence (AI). The AI may be a model configured to, using as supervised data an image of an eyeball and a direction actually viewed by the eyeball in the image, estimate the angle of the line of sight and the distance to an object in the line of sight based on an image of an eyeball. An AI program may be included in the display apparatus, or may be included in the imaging apparatus, or may be included in an external apparatus. In a case where the AI program is included in the external apparatus, the AI program is transmitted to the display apparatus through communication.

In a case where the display apparatus performs display control based on line-of-sight detection, the display apparatus can be suitably applied to smartglasses further including an imaging apparatus that captures outside. The smartglasses can display information regarding the captured outside in real time.

As described above, according to the present disclosure, it is possible to provide a light-emitting device in which a leakage current in a light-emitting element is reduced.

According to the present disclosure, it is possible to provide a light-emitting device in which a decrease in the characteristics of the light-emitting device due to the provision of a silicide layer is reduced.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2024-014805, filed Feb. 2, 2024, which is hereby incorporated by reference herein in its entirety.

What is claimed is:

1. A light-emitting device comprising:
a light-emitting element;
a first transistor and a second transistor provided on a first surface of a silicon substrate;
an insulating layer disposed between the light-emitting element and the first surface; and
a third transistor provided in a peripheral circuit configured to supply an image signal to the first transistor,
wherein either of a source or a drain of the first transistor is connected to a gate electrode of the second transistor,
wherein either of a source or a drain of the second transistor is connected to the light-emitting element,
wherein the light-emitting device includes a silicide layer in at least any one of a source, a drain, or a gate electrode of the third transistor, and the silicide layer is in contact with the insulating layer, and
wherein the light-emitting device includes a region where a silicide layer is not provided between at least any one of the source, the drain, or a gate electrode of the first transistor and the insulating layer.

2. A light-emitting device comprising:
a light-emitting element;
a first transistor and a second transistor provided on a first surface of a silicon substrate; and
a third transistor provided in a peripheral circuit configured to supply an image signal to the first transistor,
wherein either of a source or a drain of the first transistor is connected to a gate electrode of the second transistor,
wherein either of a source or a drain of the second transistor is connected to the light-emitting element,
wherein the light-emitting device includes a salicide structure in at least any one of a source, a drain, or a gate electrode of the third transistor, and
wherein the light-emitting device does not include a salicide structure in at least any one of the source, the drain, or a gate electrode of the first transistor.

3. The light-emitting device according to claim 1, wherein in a cross section perpendicular to the first surface, the light-emitting device includes a region where a silicide layer is not provided between at least any one of the source, the drain, or the gate electrode of the second transistor and the insulating layer.

4. The light-emitting device according to claim 2, wherein the light-emitting device does not include a salicide structure in at least any one of the source, the drain, or the gate electrode of the second transistor.

5. The light-emitting device according to claim 1, further comprising a fourth transistor disposed between a power supply configured to supply a current to the light-emitting element and the second transistor,
wherein in a cross section perpendicular to the first surface, the light-emitting device includes a region where a silicide layer is not provided between at least any one of a source, a drain, or a gate electrode of the fourth transistor and the insulating layer.

6. The light-emitting device according to claim 2, further comprising a fourth transistor disposed between a power supply configured to supply a current to the light-emitting element and the second transistor,
wherein the light-emitting device does not include a salicide structure in at least any one of a source, a drain, or a gate electrode of the fourth transistor.

7. The light-emitting device according to claim 5, further comprising a fifth transistor disposed between a terminal connected to the light-emitting element between the drain and the source of the second transistor, and a terminal having a potential lower than a potential of a power supply configured to supply a current to the light-emitting element,
wherein in a cross section perpendicular to the first surface, the light-emitting device includes a region where a silicide layer is not provided between at least any one of a source, a drain, or a gate electrode of the fifth transistor and the insulating layer.

8. The light-emitting device according to claim 6, further comprising a fifth transistor disposed between a terminal connected to the light-emitting element between the drain and the source of the second transistor, and a terminal having a potential lower than a potential of a power supply configured to supply a current to the light-emitting element,
wherein the light-emitting device does not include a salicide structure in at least any one of a source, a drain, or a gate electrode of the fifth transistor.

9. The light-emitting device according to claim 1,
wherein an impurity concentration of a diffusion region of the source of the second transistor and an impurity concentration of a diffusion region of the drain of the second transistor have concentration distributions having peak concentrations in a first direction from the source to the drain,
wherein an impurity concentration of a diffusion region of the source of the third transistor and an impurity concentration of a diffusion region of the drain of the third transistor have concentration distributions having peak concentrations in a second direction from the source to the drain, and
wherein a peak concentration of impurities in the diffusion region of the source or the drain of the second transistor is smaller than a peak concentration of impurities in the diffusion region of the source or the drain of the third transistor.

10. The light-emitting device according to claim 1,
wherein an impurity concentration of a diffusion region of the source of the first transistor and an impurity concentration of a diffusion region of the drain of the first transistor have concentration distributions having peak concentrations in a third direction from the source to the drain,
wherein an impurity concentration of a diffusion region of the source of the third transistor and an impurity concentration of a diffusion region of the drain of the third transistor have concentration distributions having peak concentrations in a second direction from the source to the drain, and
wherein a peak concentration of impurities in the diffusion region of the source or the drain of the first transistor is smaller than a peak concentration of impurities in the diffusion region of the source or the drain of the third transistor.

11. The light-emitting device according to claim 1, further comprising a fourth transistor disposed between a power supply configured to supply a current to the light-emitting element and the second transistor,
wherein the fourth transistor includes a source, a drain, and a gate electrode,
wherein an impurity concentration of a diffusion region of the source of the fourth transistor and an impurity concentration of a diffusion region of the drain of the fourth transistor have concentration distributions having peak concentrations in a fourth direction from the source to the drain,
wherein an impurity concentration of a diffusion region of the source of the third transistor and an impurity concentration of a diffusion region of the drain of the third transistor have concentration distributions having peak concentrations in a second direction from the source to the drain, and
wherein a peak concentration of impurities in the diffusion region of the source or the drain of the fourth transistor is smaller than a peak concentration of impurities in the diffusion region of the source or the drain of the third transistor.

12. The light-emitting device according to claim 11, further comprising a fifth transistor disposed between a terminal connected to the light-emitting element between the drain and the source of the second transistor, and a terminal having a potential lower than a potential of a power supply configured to supply a current to the light-emitting element,
wherein an impurity concentration of a diffusion region of a source of the fifth transistor and an impurity concentration of a diffusion region of a drain of the fifth transistor have concentration distributions having peak concentrations in a fifth direction from the source to the drain,
wherein an impurity concentration of a diffusion region of the source of the third transistor and an impurity concentration of a diffusion region of the drain of the third transistor have concentration distributions having peak concentrations in a second direction from the source to the drain, and
wherein a peak concentration of impurities in the diffusion region of the source or the drain of the fifth transistor is smaller than a peak concentration of impurities in the diffusion region of the source or the drain of the third transistor.

13. The light-emitting device according to claim 1, wherein the first transistor includes halo injection layers in diffusion regions of the source and the drain, and the halo injection layers have a polarity opposite to a polarity of the diffusion regions.

14. The light-emitting device according to claim 13,
wherein the third transistor includes halo injection layers in diffusion regions of the source and the drain, and the halo injection layers have a polarity opposite to a polarity of the diffusion regions, and
wherein peak concentrations of impurity concentrations of the halo injection layers of the first transistor are different from peak concentrations of impurity concentrations of the halo injection layers of the third transistor.

15. The light-emitting device according to claim 1, further comprising a fourth transistor disposed between a power supply configured to supply a current to the light-emitting element and the second transistor,
wherein the fourth transistor includes halo injection layers in diffusion regions of a source and a drain,
wherein the halo injection layers have a polarity opposite to a polarity of the diffusion regions, and
wherein peak concentrations of impurity concentrations of halo injection layers of the third transistor are different from peak concentrations of impurity concentrations of the halo injection layers of the fourth transistor.

16. The light-emitting device according to claim 15, further comprising a fifth transistor disposed between a terminal connected to the light-emitting element between the drain and the source of the second transistor, and a terminal having a potential lower than a potential of a power supply configured to supply a current to the light-emitting element,
wherein the fifth transistor includes halo injection layers in diffusion regions of a source and a drain, and the halo injection layers have a polarity opposite to a polarity of the diffusion regions, and
wherein peak concentrations of impurity concentrations of halo injection layers of the third transistor are different from peak concentrations of impurity concentrations of the halo injection layers of the fifth transistor.

17. The light-emitting device according to claim 1, wherein the peripheral circuit is provided on the first surface of the silicon substrate.

18. The light-emitting device according to claim 1, wherein the peripheral circuit is disposed on a second silicon substrate different from the silicon substrate.

19. A display apparatus comprising:
the light-emitting device according to claim 1; and
an image control unit configured to transmit an image control signal to the peripheral circuit,
wherein the light-emitting element emits light according to the image control signal.

20. A photoelectric conversion apparatus comprising:
an optical unit including a plurality of lenses;
an imaging element configured to receive light passing through the optical unit; and
a display unit configured to display an image captured by the imaging element,
wherein the display unit is the display apparatus according to claim 19.

21. An electronic device comprising:
the display apparatus according to claim 19;
a housing in which the display apparatus is provided; and
a communication unit provided in the housing and configured to communicate with outside.

22. A method for manufacturing a light-emitting device comprising:
a light-emitting element;
a first transistor and a second transistor provided on a first surface of a silicon substrate; and
a third transistor provided in a peripheral circuit configured to supply an image signal to the first transistor,
wherein either of a source or a drain of the first transistor is connected to a gate electrode of the second transistor, and
wherein either of a source or a drain of the second transistor is connected to the light-emitting element,
the method comprising:
providing the light-emitting device;
forming an opening corresponding to at least any one of a source, a drain, or a gate electrode of the third transistor, and providing an insulating layer in the source, the drain, or the gate electrode of the second transistor; and
after providing the insulating layer, forming a metal layer that covers the second and third transistors, and forming a silicide layer in at least any one of the source, the drain, or the gate electrode of the third transistor.

23. The method for manufacturing a light-emitting device according to claim 22, the method further comprising:
after forming the silicide layer, providing an insulating layer on the silicide layer;
forming a first opening in the insulating layer; and
forming a contact wire in the first opening.

24. The method for manufacturing a light-emitting device according to claim 23, wherein in a planar view of the first surface, the first opening overlaps a region where the silicide layer is formed in the third transistor.

25. The method for manufacturing a light-emitting device according to claim 22, the method further comprising:
providing an insulating layer that covers the first or second transistor in a state where a silicide layer is not formed in any of the source, the drain, or a gate electrode of the first transistor and the source, the drain, or the gate electrode of the second transistor;
forming a second opening in the insulating layer; and
forming a contact wire in the second opening.

26. The method for manufacturing a light-emitting device according to claim 25, wherein in a planar view of the first surface, the second opening overlaps a region where the silicide layer is formed in the first or second transistor.
